(19) United States
(12) Patent Application Publication
(10) Pub. No.: US 2019/0233280 A1
(43) Pub. Date: Aug. 1, 2019

(54) METHOD FOR PROCESSING SILICON WAFER WITH THROUGH CAVITY STRUCTURE

(71) Applicant: Shenyang Silicon Technology Co., Ltd., Shenyang (CN)

(72) Inventor: Xiang LI, Fushun City (CN)

(73) Assignee: Shenyang Silicon Technology Co., Ltd., Shenyang (CN)

(21) Appl. No.: 16/213,019

(22) Filed: Dec. 7, 2018

(30) Foreign Application Priority Data
Jan. 26, 2018 (CN) 201810075852.5

(51) Int. Cl. B81C 1/00; B81B 1/00

(52) U.S. Cl. CPC B81C 1/00047; B32B 37/06; B81C 1/00507; B81C 1/00357; B81C 1/00849; B81B 1/004; B81C 2201/0116; B81C 2201/0125; B81C 2201/019; B81C 2201/0194; B81C 2201/0192; B81C 2201/0178; B81B 2203/0315; B81B 2203/0353; B81C 1/00087

(57) ABSTRACT

A method for processing a silicon wafer with a through cavity structure. The method is operated in accordance with the following sequence: performing ion implantation on a silicon wafer or pattern wafer; implanting a dummy substrate; bonding the silicon wafer to the pattern wafer; performing grinding and polishing, and thinning the pattern wafer to a depth exposing the pattern; bonding; and peeling the dummy substrate. Compared with the prior art, the present invention is standard in operation, and the product quality can be effectively guaranteed. The product has high cost performance and excellent comprehensive technical effect. The present invention has expectable relatively large economic values and social values.

### FIELD

The present invention relates to the field of processing technologies for a silicon wafer, and in particular, to a method for processing a silicon wafer with a through cavity structure.

### BACKGROUND

With the rapid development of the MEMS technology, more and more requirements on new MEMS structures have arisen, but many structures are faced with the dilemma of incapability of manufacturing due to the constraints of processing hardware equipment. When the hardware cannot meet the requirements, engineers and technicians are required to develop new technologies to overcome such a paradox.

The MEMS with a through cavity is one of the special structures. Different from the ordinary MEMS cavity which is buried in the silicon wafer in a final structure, the through cavity needs to be finally exposed. Most of the current silicon wafer processing devices uses vacuum to grab and process the silicon wafer, and the cavity which lays through the entire silicon wafer will destroy the vacuum, which directly affects the devices to complete the action. For example, the conventional machining finally needs to use a grinding and polishing machine to perform grinding twice to completely expose the part covered in the pattern wafer original, so as to form the through structure. However, the interference of the pattern in the grinding process of the second time will affect vacuum sealing. After the cavity is opened, the vacuum is completely destroyed. A grinding and polishing cabinet cannot fix the silicon wafer or transfer the silicon wafer. As a result, the grinding cannot be finished according to the requirements or the cabinet is even damaged.

In order to solve the problem of vacuum leakage caused by processing the through cavity, the MEMS processing technology of implanting and peeling a dummy substrate is developed, so as to solve the vacuum leakage and peel the dummy substrate which is not needed by the final structure. The technology of implanting and peeling the dummy substrate is formed by a bonding technology, an ion implantation technology and a microwave splitting technology. Before forming the final structure, the dummy substrate plays a role of encapsulating the cavity to avoid vacuum leakage. Under a normal temperature or a high temperature field and under a normal pressure or vacuum air pressure environment, the common silicon wafer and the pattern wafer are bonded into one wafer by the bonding technology, thereby achieving encapsulation of the pattern cavity. The dummy substrate is the undesired part and thus needs to be peeled from the final structure. The peeling of the dummy substrate includes performing ion implantation on the common silicon wafer or pattern wafer before bonding. Hydrogen ions and helium atoms are the most commonly used implantation agents for separation. Finally, by the microwave splitting technology, the kinetic energy for implanting the ions is improved to cause the ions to be converged to generate small bubbles. The small bubbles are extruded by the silicon wafer to tend to move along the direction of a bonding surface, and converge in an implantation layer to form complete large bubbles. The macroscopic separation between the dummy substrate and the main body structure is formed, the effect of peeling the dummy substrate is realized, and the through structure does not need to be realized by a grinding machine.

### SUMMARY

An objective of the present invention is to provide a method for processing a silicon wafer with a through cavity structure with an excellent technical effect.

The present invention provides a method for processing a silicon wafer with a through cavity structure, wherein the method is operated in accordance with the following requirements in sequence.

(1) Ion implantation is performed on a silicon wafer or a pattern wafer. The processing of step (1) aims at the pretreatment for finally peeling a dummy substrate by a microwave peeling technology.

(2) The dummy substrate is implanted, and the silicon wafer is bonded to the pattern wafer. The bonded silicon wafer is the dummy substrate, and plays a role of sealing the pattern in the following steps, thereby ensuring the capability of processing of a cabinet. Step (2) achieves the purpose of introducing the dummy substrate by a silicon wafer direct bonding technology.

(3) Grinding and polishing are performed by a mechanical grinding or/and chemical polishing method. The bonded silicon wafer, i.e., the dummy substrate, is used as a substrate, the pattern wafer is thinned, grinding is performed to the depth of exposing the pattern, and the cavity which is not originally exposed is exposed. By using mechanical grinding and the chemical polishing for grinding and polishing, the silicon wafer can be processed to a designated thickness and an excellent roughness required by design, thereby ensuring that the surface with an excellent state is used in the subsequent process.

(4) Bonding is performed, and pattern-to-pattern bonding is performed on the two silicon wafers subjected to the steps (1) and (2). The dummy substrate is located on the upper and lower sides of the integral structure.

(5) The dummy substrate is peeled, and the dummy substrate playing a protective role is peeled by low-temperature annealing and microwave splitting operation to realize the silicon wafer of a through structure. The annealing can increase the bonding force of a bonding interface, thereby ensuring the excellent bonding state of the pattern bonding interface, and the reliability of subsequent use. The annealing treatment is favorable to enhance the bonding force of the pattern-to-pattern bonding interface, and avoids vacuum leakage caused by processing on the device after the through structure is formed. The microwave splitting is intended to increase the kinetic energy of the ions by microwaves. The moving ions collide with each other to form small bubbles. The extrusion of the silicon wafer will limit the movement of the bubbles in a direction perpendicular to the bonding interface, and the small bubbles tend to move along the direction of the bonding interface. The small bubbles are thus converged into large bubbles, and finally the separation of the silicon wafer is formed in the implantation layer, and the dummy substrate is peeled from the main body structure.

Step (3) is the pretreatment of step (4) and is for the purpose of making preparations for connecting the cavities of the two pattern wafers together. By using mechanical grinding and chemical polishing for grinding and polishing, the silicon wafer can be processed to a designated thickness and an excellent roughness required by design, thereby ensuring that the surface with an excellent state is used in the subsequent process.

The preferred requirements for the method for processing a silicon wafer with a through cavity structure are as follows.

The requirements of performing ion implantation on a silicon wafer or a pattern wafer are as follows: an implantation depth is in the range of 1 μm to 0.001 μm from the surface; and the requirements on the parameters of hydrogen ion implantation are the energy of 10 to 120 KeV, the dose of 1E15 to 9E16, and the beam of 1-20 mA. By parameter control, it can be ensured that the surface of the silicon wafer subjected to implantation has better state, and does not negatively affect subsequent processing.

The specific requirements of bonding the silicon wafer to the pattern wafer are that the roughness of the silicon wafer is less than or equal to 5 nm; the silicon wafer and the pattern wafer are used in direct contact, and are combined into a whole by means of intermolecular forces on the surfaces thereof.

The silicon wafer is bonded to the pattern wafer by using a plasma-enhanced direct bonding method. Specifically, the common silicon wafer and the pattern wafer are subjected to plasma enhancement for 0-90 s, the common silicon wafer is bonded to the surface with the pattern, and the common silicon wafer is the dummy substrate.

With the requirements of the industry on a multi-bonding force and the reduction of a thermal budget, the plasma-enhanced direct bonding technology is developed subsequently and can achieve a faster processing speed and a lower subsequent annealing temperature.

The temperature requirement of annealing the bonded wafer when the dummy substrate is peeled is 150 to 450° C.

Before performing ion implantation on a silicon wafer or a pattern wafer, the following operation is performed: performing chemical wet cleaning on the pattern wafer to remove contaminants to reduce metal and organic pollution; then performing oxidation treatment to uniformly grow an oxide layer having a thickness of 0.1-0.5 μm on the front surface, the back surface and the edge and in the cavity of the pattern wafer at 800-1150° C.

After the dummy substrate on both sides is peeled off by using the microwave splitting technology, the oxide layer of the silicon wafer having a through cavity structure is cleaned and rinsed by using HF to remove a separation interface, so as to form the surface having an excellent state.

Compared with the prior art, the present invention is standard in operation, and the product quality can be effectively guaranteed. The product has high cost performance and excellent comprehensive technical effects. The present invention has expectable relatively large economic values and social values.

### BRIEF DESCRIPTION OF THE DRAWINGS

FIG. 1 is a principle schematic diagram of a method for processing a silicon wafer with a through cavity structure.

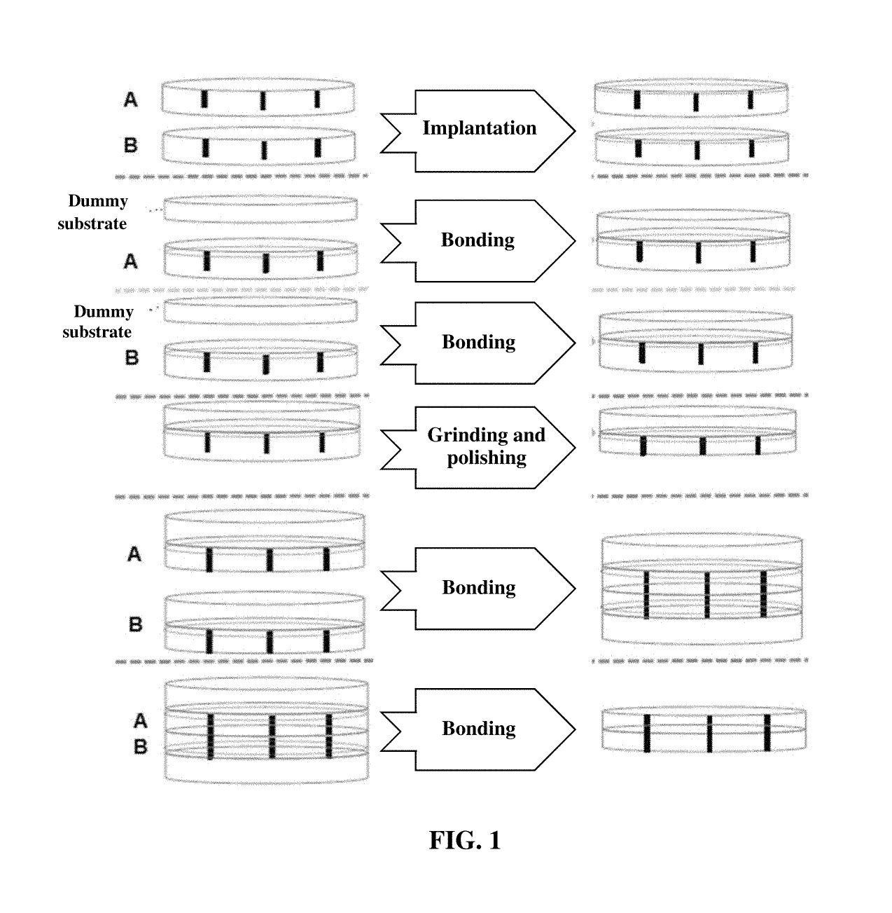

### DETAILED DESCRIPTION

### Embodiment 1

A method for processing a silicon wafer with a through cavity structure is operated in accordance with the following requirements in sequence.

(1) Ion implantation is performed on a silicon wafer or a pattern wafer. The processing of step (1) aims at the pretreatment for finally peeling a dummy substrate by a microwave peeling technology.

(2) The dummy substrate is implanted, and the silicon wafer is bonded to the pattern wafer. The bonded silicon wafer is the dummy substrate, and plays a role of sealing the pattern in the following steps, thereby ensuring the capability of processing of a cabinet. Step (2) achieves the purpose of introducing the dummy substrate by a silicon wafer direct bonding technology.

(3) Grinding and polishing are performed by a mechanical grinding or/and chemical polishing method, the bonded silicon wafer, i.e., the dummy substrate is used as a substrate, the pattern wafer is thinned, grinding is performed to the depth of exposing the pattern, and the cavity which is not originally exposed is exposed. By using mechanical grinding and chemical polishing for grinding and polishing, the silicon wafer can be processed to a designated thickness and an excellent roughness required by design, thereby ensuring that the surface with an excellent state is used in the subsequent process.

(4) Bonding is performed, and pattern-to-pattern bonding is performed on the two silicon wafers subjected to the steps (1) and (2). The dummy substrate is located on the upper and lower sides of the integral structure.

(5) The dummy substrate is peeled, and the dummy substrate playing a protective role is peeled by low-temperature annealing and microwave splitting operation to realize the silicon wafer of a through structure. The annealing can increase the bonding force of a bonding interface, and ensure the excellent bonding state of the pattern bonding interface, thereby ensuring the reliability of subsequent use. The annealing treatment is favorable to enhance the bonding force of the pattern-to-pattern bonding interface, and avoids vacuum leakage caused by processing on the machine after the through structure is formed. The microwave splitting is to increase the kinetic energy of the ions by microwave. The moving ions collide with each other to form small bubbles. The extrusion of the silicon wafer will restrict the movement of the bubbles in a direction perpendicular to the bonding interface, and the small bubbles tend to move along the direction of the bonding interface. The small bubbles are thus converged into large bubbles, and finally the separation of the silicon wafer is formed in the implantation layer, and the dummy substrate is peeled from the main body structure.

Step (3) is the pretreatment of step (4) and is for the purpose of making preparations for connecting the cavities of the two pattern wafers together. By using mechanical grinding and chemical polishing for grinding and polishing, the silicon wafer can be processed to a designated thickness and an excellent roughness required by design, thereby ensuring that the surface with an excellent state is used in the subsequent process.

The requirements of performing ion implantation on a silicon wafer or a pattern wafer are as follows: an implantation depth is in the range of 1 μm to 0.001 μm from the surface; and the requirements on the parameters of hydrogen ion implantation are the energy of 10 to 120 KeV, the dose of 1E15 to 9E16, and the beam of 1-20 mA. By parameter control, it can be ensured that the surface of the silicon wafer subjected to implantation has better state, and does not negatively affect subsequent processing.

The specific requirements of bonding the silicon wafer to the pattern wafer are that the roughness of the silicon wafer is less than or equal to 5 nm; the silicon wafer and the pattern wafer are used in direct contact, and are combined into a whole by means of intermolecular forces on the surfaces thereof.

The silicon wafer is bonded to the pattern wafer by using a plasma-enhanced direct bonding method. Specifically, the common silicon wafer and the pattern wafer are subjected to plasma enhancement for 0-90 s, the common silicon wafer is bonded to the surface with the pattern, and the common silicon wafer is the dummy substrate. With the requirements of the industry on a multi-bonding force and the reduction of a thermal budget, the plasma-enhanced direct bonding technology is developed subsequently and can achieve a faster processing speed and a lower subsequent annealing temperature.

The temperature requirement of annealing the bonded wafer when the dummy substrate is peeled is 150 to 450° C.

Before performing ion implantation on a silicon wafer or a pattern wafer, the following operation is performed: performing chemical wet cleaning on the pattern wafer to remove contaminants to reduce metal and organic pollution; then performing oxidation treatment to uniformly grow an oxide layer having a thickness of 0.1-0.5 μm on the front surface, the back surface and the edge and in the cavity of the pattern wafer at 800-1150° C.

After the dummy substrate on both sides is peeled off by using the microwave splitting technology, the oxide layer of the silicon wafer having a through cavity structure is cleaned and rinsed by using HF to remove a separation interface, so as to form a surface having an excellent state.

Compared with the prior art, the present invention is standard in operation, and the product quality can be effectively guaranteed. The product has high cost performance and excellent comprehensive technical effect. The present invention has expectable relatively large economic values and social values.

### Embodiment 2

A method for processing a silicon wafer with a through cavity structure is operated in accordance with the following requirements in sequence.

(1) Chemical wet cleaning is performed on the pattern wafer to remove contamination and reduce metal and organic pollution, then oxidation treatment is performed, and the oxide layer with the thickness of 0.1-0.5 μm is uniformly grown in the front, the back and the edge and in the cavity of the pattern wafer at 800-1150° C.

(2) The pattern wafer is subjected to the hydrogen ion implantation with the energy of 10˜120 Kev, the dose of 1E15 to 9E16, and the beam of 1-20 mA.

(3) A common silicon wafer and the pattern wafer are subjected to plasma enhancement for 0 to 90 s, the common silicon wafer is bonded to the surface with the pattern, and the common silicon wafer is a dummy substrate.

(4) The bonding wafer subjected to step (3) is used for grinding the pattern wafer, the dummy substrate is used as a substrate, the pattern piece is thinned and grinding is performed to a depth of the exposing the pattern.

(5) The two wafers subjected to step (4) are subjected to plasma-enhanced bonding for 0 to 90 s, the exposed pattern is sealed, and the dummy substrate comes out from the upper and lower sides of the integral structure.

(6) The bonded wafer subjected to step (5) is subjected to annealing treatment at 150 to 450° C. to enhance the bonding force of the pattern-to-pattern bonding interface, thereby avoiding vacuum leakage caused by the processing on the machine after the through-structure is formed.

(7) The dummy substrate on both sides is peeled off by using a microwave splitting technology.

(8) For the silicon wafer with the through cavity structure, the oxide layer is cleaned and rinsed by using HF, and the separation interface is removed to form a surface having an excellent surface state.

1. A method for processing a silicon wafer with a through cavity structure, comprising:
(1) performing ion implantation on a silicon wafer or a pattern wafer;
(2) implanting a dummy substrate, and bonding the silicon wafer to the pattern wafer;
(3) grinding and polishing by a mechanical grinding or/and chemical polishing method, using the dummy substrate as a substrate, thinning the pattern wafer, grinding the pattern wafer to a depth of exposing the pattern, and exposing a cavity which is not originally exposed;
(4) performing pattern-to-pattern bonding on the two silicon wafers subjected to the steps (1) and (2); and
(5) peeling the dummy substrate playing a protective role by low-temperature annealing and microwave splitting operation to realize the silicon wafer of a through structure.

2. The method for processing a silicon wafer with a through cavity structure according to claim 1, further comprising:
an implantation depth is in a range of 1 μm to 0.001 μm from the surface; and the hydrogen ion implantation are the energy of 10 to 120 KeV, the dose of 1E15 to 9E16, and the beam of 1-20 mA; and
wherein for bonding the silicon wafer to the pattern wafer, a roughness of the silicon wafer is less than or equal to 5 nm; and the silicon wafer and the pattern wafer are used in direct contact, and are combined into a whole by means of intermolecular forces on the surfaces thereof.

3. The method for processing a silicon wafer with a through cavity structure according to claim 2, wherein the silicon wafer is bonded to the pattern wafer by using a plasma-enhanced direct bonding method.

4. The method for processing a silicon wafer with a through cavity structure according to claim 3, wherein the temperature of annealing the bonded wafer when the dummy substrate is peeled is 150 to 450° C.

5. The method for processing a silicon wafer with a through cavity structure according to claim 1, wherein before performing ion implantation on the silicon wafer or the pattern wafer, the following operation is performed: performing chemical wet cleaning on the pattern wafer to remove contaminants to reduce metal and organic pollution; then performing oxidation treatment to uniformly grow an oxide layer having a thickness of 0.1-0.5 μm on the front surface, the back surface and the edge and in the cavity of the pattern wafer at 800-1150° C.; and
after the dummy substrate on both sides is peeled off by using a microwave splitting technology, cleaning and rinsing the oxide layer of the silicon wafer having a through cavity structure by using HF to remove a separation interface to form a surface having an excellent state.

6. The method for processing a silicon wafer with a through cavity structure according to claim 2, wherein before performing ion implantation on the silicon wafer or the pattern wafer, the following operation is performed: performing chemical wet cleaning on the pattern wafer to remove contaminants to reduce metal and organic pollution; then performing oxidation treatment to uniformly grow an oxide layer having a thickness of 0.1-0.5 μm on the front surface, the back surface and the edge and in the cavity of the pattern wafer at 800-1150° C.; and
after the dummy substrate on both sides is peeled off by using a microwave splitting technology, cleaning and rinsing the oxide layer of the silicon wafer having a through cavity structure by using HF to remove a separation interface to form a surface having an excellent state.

7. The method for processing a silicon wafer with a through cavity structure according to claim 3, wherein before performing ion implantation on the silicon wafer or the pattern wafer, the following operation is performed: performing chemical wet cleaning on the pattern wafer to remove contaminants to reduce metal and organic pollution; then performing oxidation treatment to uniformly grow an oxide layer having a thickness of 0.1-0.5 μm on the front surface, the back surface and the edge and in the cavity of the pattern wafer at 800-1150° C.; and
after the dummy substrate on both sides is peeled off by using a microwave splitting technology, cleaning and rinsing the oxide layer of the silicon wafer having a through cavity structure by using HF to remove a separation interface to form a surface having an excellent state.

8. The method for processing a silicon wafer with a through cavity structure according to claim 4, wherein before performing ion implantation on the silicon wafer or the pattern wafer, the following operation is performed: performing chemical wet cleaning on the pattern wafer to remove contaminants to reduce metal and organic pollution; then performing oxidation treatment to uniformly grow an oxide layer having a thickness of 0.1-0.5 μm on the front surface, the back surface and the edge and in the cavity of the pattern wafer at 800-1150° C.; and
after the dummy substrate on both sides is peeled off by using a microwave splitting technology, cleaning and rinsing the oxide layer of the silicon wafer having a through cavity structure by using HF to remove a separation interface to form a surface having an excellent state.
